(19) United States
(12) Patent Application Publication
(10) Pub. No.: US 2014/0301137 A1
(43) Pub. Date: Oct. 9, 2014

(54) PHASE-CHANGE MEMORY DEVICE HAVING PHASE-CHANGE REGION DIVIDED INTO MULTI LAYERS AND OPERATING METHOD THEREOF

(71) Applicant: SK hynix Inc., Gyeonggi-do (KR)

(72) Inventors: Jin Hyock KIM, Gyeonggi-do (KR); Su Jin CHAE, Gyeonggi-do (KR); Young Seok KWON, Gyeonggi-do (KR); Hae Chan PARK, Gyeonggi-do (KR)

(21) Appl. No.: 14/309,430

(22) Filed: Jun. 19, 2014

Related U.S. Application Data
(63) Continuation-in-part of application No. 13/331,254, filed on Dec. 20, 2011.

(30) Foreign Application Priority Data
Oct. 20, 2011 (KR) 10-2011-0107632

(51) Int. Cl. H01L 45/00; G11C 13/00

(52) U.S. Cl. CPC H01L 45/12; G11C 13/0004
USPC 365/163; 257/2

(57) ABSTRACT

A phase-change memory device including a multi-level cell and an operation method thereof are provided. The device includes a first phase-change material layer to which a current is provided from a heating electrode, and a second phase-change material layer formed with continuity to the first phase-change material layer and having a different width from the first phase-change material layer, and to which a current is provided from the heating electrode. The second phase-change material layer includes a material having smaller resistivity and a lower crystallization rate than the first phase-change material layer.

### CROSS-REFERENCES TO RELATED APPLICATION

The application is a continuation-in-part of the U.S. patent application Ser. No. 13/331,254 filed Dec. 20, 2011 and titled “PHASE-CHANGE MEMORY DEVICE HAVING MULTI-LEVEL CELL AND A METHOD OF MANUFACTURING THE SAME”, which is incorporated here in by reference in its entirety.

### BACKGROUND OF THE INVENTION

1. Technical Field

The inventive concept relates to a nonvolatile memory device and an operating method thereof, and more particularly, to a phase-change memory device including a multi-level cell and an operating method thereof.

2. Related Art

Research has been conducted on nonvolatile memory devices such as phase-change memory devices to implement a multi-level cell while minimizing modification of a cell shape.

Technology, in which a stepwise write voltage is provided to a bit line of a phase-change memory device to vary a degree of phase-change of a phase-change material, thereby implementing multi levels, has been suggested.

However, in the phase-change memory device of the related art, as shown in FIG. 1, since a phase-change material layer is formed to overlap a bit line 20 and heating electrodes BEC1, BEC2, and BEC3 which are in contact with one phase-change line 10 are densely formed, it is difficult to implement accurately multi levels due to influence of adjacent cells cell1, cell2, and cell3.

### SUMMARY

According to an aspect of an exemplary embodiment, a phase-change memory device includes a first phase-change material layer to which a current is provided from a heating electrode, and a second phase-change material layer formed with continuity to the first phase-change material layer and having a different width from the first phase-change material layer, and to which a current is provided from the heating electrode. The second phase-change material layer may include a material having smaller resistivity and a lower crystallization rate than the first phase-change material layer.

According to an aspect of an exemplary embodiment, a phase-change memory device includes a first phase-change region having a first caliber, and a second phase-change region extended upwardly with continuity to the first phase-change region and having a second caliber greater than the first caliber. The second phase-change region may include a material having smaller resistivity and a lower crystallization rate than the first phase-change region.

According to an aspect of an exemplary embodiment, a method of operating a phase-change memory device which includes a first phase-change material layer to which a current is provided from a heating electrode, and a second phase-change material layer formed with continuity to the first phase-change material layer and having a different width from the first phase-change materia layer, and to which a current is provided from the heating electrode, wherein the second phase-change material layer includes a material having smaller resistivity and a lower crystallization rate than the first phase-change material layer. The method may include, to selectively program only the first-change material layer, providing a first current having a first level for allowing only the first phase-change material layer to be phase-changed.

According to an aspect of an exemplary embodiment, method of operating a phase-change memory device which includes a first phase-change material layer to which a current is provided from a heating electrode and a second phase-change material layer formed with continuity to the first phase-change material layer and having a different width from the first phase-change materia layer, and to which a current is provided from the heating electrode, wherein the second phase-change material layer includes a material having smaller resistivity and a lower crystallization rate than the first phase-change material layer. The method may include supplying a write pulse to at least one of the first phase-change material layer and the second phase-change material layer through the heating electrode to program the phase-change memory device.

These and other features, aspects, and embodiments are described below in the section entitled “DESCRIPTION OF EXEMPLARY EMBODIMENT”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a schematic cross-sectional view illustrating a driving of a general phase-change memory device;

FIG. 2 is a cross-sectional view illustrating a phase-change memory device according to an exemplary embodiment of the inventive concept;

FIG. 3 is a graph showing a resistance level according to current application in a phase-change memory device according to an exemplary embodiment of the inventive concept;

FIGS. 4A to 4C are cross-sectional views for processes illustrating a method of manufacturing a phase-change memory device according to an exemplary embodiment of the inventive concept;

FIG. 5 is a cross-sectional view illustrating a phase-change memory device according to another exemplary embodiment;

FIG. 6 is a perspective view of a phase-change memory device according to still another exemplary embodiment of the inventive concept;

FIGS. 7A and 7B are views illustrating a phase-change memory device according to yet another exemplary embodiment of the inventive concept;

FIG. 8 is a graph showing a driving of a phase change memory device according to exemplary embodiments of the inventive concept;

FIG. 9 is a graph showing resistance-current characteristics of a phase-change material;

FIG. 10 is a graph showing properties of resistivity and a crystallization rate of a phase-change material applied to the inventive concept; and

FIG. 11 is a view explaining resistance change according to a falling time of a write pulse.

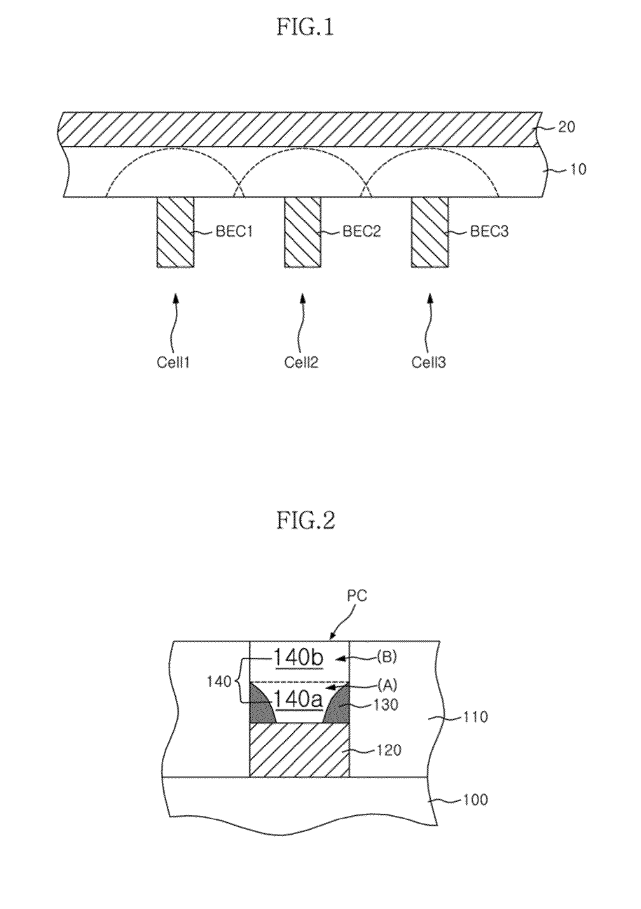

### DESCRIPTION OF EXEMPLARY EMBODIMENT

Hereinafter, exemplary embodiments will be described in greater detail with reference to the accompanying drawings.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity, Like reference numerals in the drawings denote like elements. It is also understood that when a layer is referred to as being “on” another layer or substrate, it can be directly on the other or substrate, or intervening layers may also be present.

Referring to FIG. 2, an interlayer insulating layer 110 having a phase-change region PC is formed on a semiconductor substrate resultant 100. The phase-change region PC is included in the interlayer insulating layer in a hole type.

A heating electrode 120 is formed in a bottom of the phase-change region PC, that is, in a portion of the phase-change region PC on and around a surface of the semiconductor substrate resultant 100. The heating electrode 120 may include a conductive material having high resistivity. The heating electrode 120 may be disposed below the interlayer insulting layer 110.

A spacer 130 is formed on a sidewall of the phase-change region PC on the heating electrode 120. The spacer 130 may be formed to surround the sidewall of the phase-change region PC. The spacer 130 may be formed to have a height corresponding to 30 to 60 percentages of a height in the entire sidewall of the phase-change region PC. In the exemplary embodiment, the spacer 130 may be formed to have the height of 20 to 200 nm.

The phase-change region PC is divided into a first phase-change region A and a second phase-change region B by the spacer 130.

The first phase-change region A is a region surrounded by the spacer 130 and the second phase-change region B is a region in which the spacer 130 is not formed. The first phase-change region A has a narrower diameter than the second phase-change region B by a linewidth of the spacer 130.

A first phase-change material layer 140a is buried within the first phase-change region A and a second phase-change material layer 140b is buried within the second phase-change region B. The first and second phase-change material layers 140a and 140b may include the same material. Even when the first and second phase-change material layers 140a and 140b includes the same material, the first and second phase-change material layers 140a and 140b are formed in different spaces and thus phase-change conditions of thereof become different.

That is, since the first phase-change region A has a narrower diameter than the second phase-change region B, a current density of the first phase-change region A is relatively high when a set or reset current is applied thereto. Therefore, the first phase-change region A is phase-changed faster than the second phase-change region B.

Meanwhile, since the second phase-change region B has a relatively wider diameter than the first phase-change region A, a current density of the second phase-change region B is lower than the first phase-change region A. Therefore, the phase-change region B is phase-changed later than the first phase-change region A.

Therefore, the phase-change memory device according to the exemplary embodiment has three states depending on a degree phase-change of the phase-change material layer.

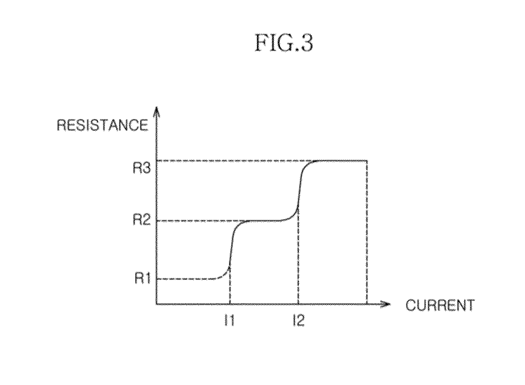

That is, as shown in FIG. 3, before a current is applied from the heating electrode, the phase-change material layer 140 is in a non-phase-change state and thus the phase-change material layer 140 has a resistance corresponding to R1.

When a first current I1 is applied to the phase-change material layer 140 through the heating electrode 120, the first phase-change material layer 140a is phase-changed. Therefore, when to viewed in the term of the entire phase-change material layer 140, the phase-change material layer 140 is partially phase-changed and thus the phase-change material layer 140 has a resistance of R2.

When a second current 12 greater than the first current I1 is applied to the phase-change material layer 140 through the heating electrode 120, the second phase-change material layer 140b is also phase-changed. Thus, the entire phase-change material layer 140 is fully phase-changed and has a resistance of R3 corresponding to the full phase-change.

The above-described phase-change memory device according to the exemplary embodiment can realize resistances of multi levels by stepwise application of a write current.

In an embodiment, the first phase-change material layer 140a and the second phase-change material layer 140b may be formed of materials having different electrical characteristics from each other. For example, the second phase-change material layer 140b may be formed of a material having smaller resistivity and a lower crystallization rate than the first phase-change material layer 140a. From different points of view, the first phase-change material layer 140a may be formed of a material having larger resistivity and a higher crystallization rate than the second phase-change material layer 140b.

FIG. 9 is a graph showing resistance-current characteristics of a phase-change material. The material having relatively large resistivity and a relatively high crystallization rate may be phase-changed even with a small amount of current as indicated by \textcircled{1} of FIG. 9. A relatively large amount of current is needed to phase-change the material having relatively small resistivity and a relatively low crystallization rate as indicated by \textcircled{2} of FIG. 9.

An amount of current applied to the phase-change material proportional to the volume of a phase-change region within the phase-change material. That is, as an amount of applied current is increased, the volume of the phase-change region is increased.

Therefore, phase-change in the first phase-change material layer 140a and the second phase-change material layer 140b may be controlled through an amount of current applied thereto, Both the first phase-change material layer 140a and the second phase-change material layer 140b may not be phase-changed, or may be phase-changed. Further, any one of the first phase-change material layer 140a and the second phase-change material layer 140b may be selectively phase-changed.

That is, as illustrated in FIG. 3, before the current is applied from the heating electrode 120, the phase-change material layer 140 is in a non-phase-change state, that is, the phase-change material layer 140 has the resistance corresponding to R1.

When the first current I1 is applied to the phase-change material layer 140 through the heating electrode 120, the first phase-change material layer 140a is phase-changed. Therefore, when viewed in terms of the entire phase-change material layer 140, the phase-change material layer 140 is partially phase-changed, and thus the phase-change material layer 140 has the resistance corresponding to R2.

When the second current I2 greater than the first current I1 is applied to the phase-change material layer 140 through the heating electrode 120, the second phase-change material layer 140b is also phase-changed. Therefore, the entire phase-change material layer 140 is fully phase-changed, and has the resistance of R3 corresponding to the full phase-change.

The above-described phase-change memory device according to the exemplary embodiment can realize resistances of multi levels by stepwise application of a write current.

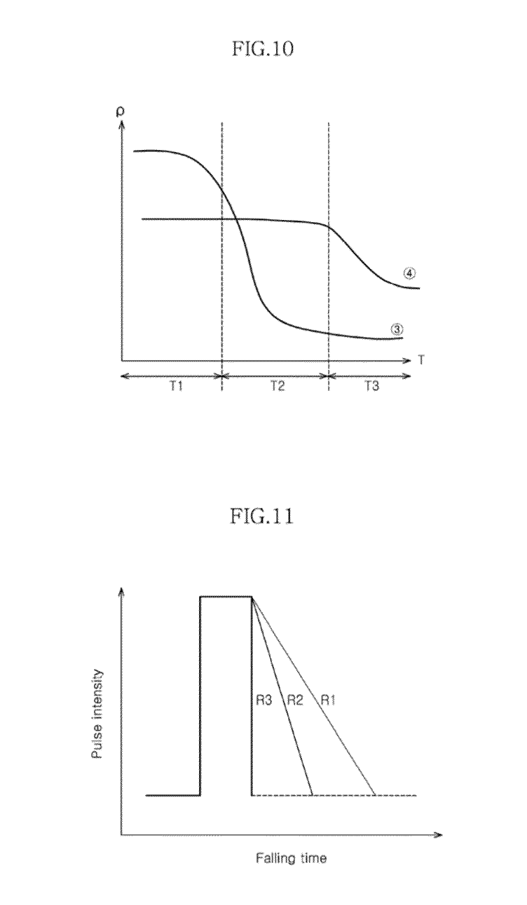

The first phase-change material layer 140a has the property that the resistivity ρ is large and the crystallization rate is high as compared to the second phase-change material layer 140b as indicated in \textcircled{3} of FIG. 10. The second phase-change material layer 140b has the property that the resistivity ρ is small and the crystallization rate is low as compared to the first phase-change material layer 140a as indicated in \textcircled{4} of FIG. 10.

Therefore, in the T1 period, both the first phase-change material layer 140a and the second phase-change material layer 140b have a high-resistance state. In the T2 period, the first phase-change materia 140a has a low-resistance state, and the second phase-change material layer 140b has a high-resistance state. In the T3 period, both the first phase-change material layer 140a and the second phase-change material layer 140b have a low-resistance state.

Accordingly, even when the same size of pulse is applied through the heating electrode 120, the low-resistance state R1, the middle-resistance state R2, and the high-resistance state R3 in the phase-change material layer 140 may be implemented according to the current application time as illustrated in FIG. 3.

That is, the multi-level cell having the resistance of various levels may be implemented according to an application time of the write current.

The phase-change memory device according to the exemplary embodiment may have a stable resistance distribution in each resistance level as illustrated in FIG. 3. This means that a data eye is wide. When the write operation is performed through the program and verifying operation, it may fast check that the resistance distribution of each memory cell is corresponding to which resistance level during a verifying operation, and thus the write rate may be improved.

FIG. 11 illustrates a method of implementing a multi-level cell according to control of a falling time of a write current. Through control of the falling time while the write pulse having the same density is applied, a degree of phase-change of the phase-change material layer 140 may be controlled in such a manner that the phase-change material layer 140 has various resistances. Therefore, the multi-level cell may be implemented. In particular, when the phase-change material layer 140 is controlled to have a high-resistance state, the write pulse may be abruptly shut down. The falling time of the write pulse may be maintained for a long time according to the desired low-resistance level of the phase-change material layer 140.

In the phase-change memory device according to the exemplary embodiment, the first and second phase-change material layers 140a and 140b are continuously formed without break and thus an bulky erase can performed by providing a voltage once. That is, in general, multi layers in phase-change material layer for implementing multi levels are divided into each other. A separate erase for each of the multi layers in phase-change material layer required. However, in the exemplary embodiment, since a plurality of phase-change regions are formed within one contact hole, an erase on the phase-change material layer can be realized by providing an erase voltage once.

Subsequently, a method of manufacturing the phase-change memory device will be described.

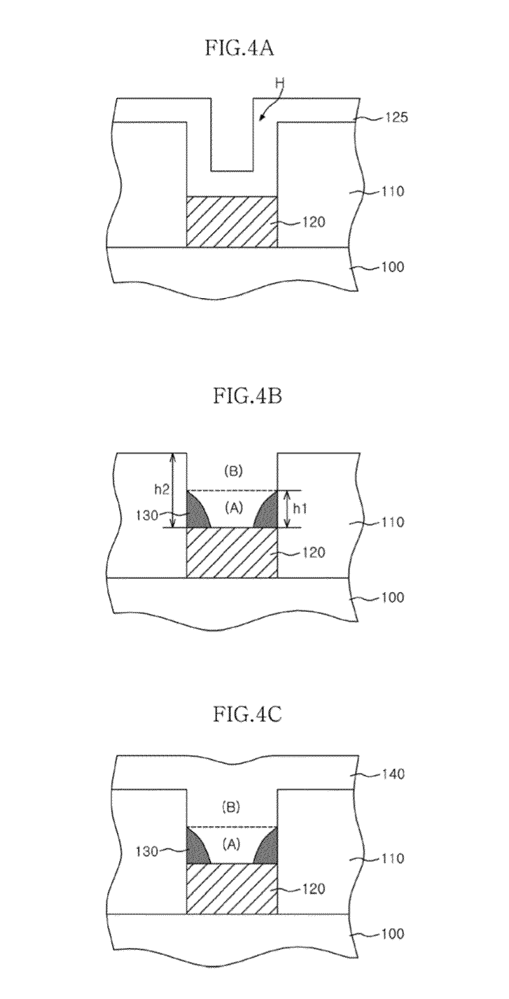

Referring to FIG. 4A, an interlayer insulating layer 110 is formed on a semiconductor substrate resultant 100. Although not shown, the semiconductor substrate resultant 100 may a semiconductor substrate in which a word line and a switching device are formed. The interlayer insulating layer 110 may include a first insulating material, for example, a silicon oxide layer. A portion of the interlayer insulating layer 110 is etched to form a contact hole H which is to be a phase-charge region. A heating electrode 120 is formed on a bottom of the contact hole H. The heating electrode 120 may be formed by depositing a conductive material on the interlayer insulating layer 110 in which the contact hole H is formed and overetching the conductive material to remain on the bottom of the contact hole H. In addition, the heating electrode 120 may be formed on the semiconductor substrate resultant 100 before the interlayer insulating layer 110 is formed. The heating electrode 110 may include any one of titanium/titanium nitride (Ti/TiN), Ti/titanium silicon nitride (Ti/TiSiN), Ti/titanium aluminum nitride (Ti/TiAlN), Ti/tantalum nitride (Ti/TaN), Ti/TaSiN, and Ti/TaAlN. A thickness of a Ti layer constituting the heating electrode 110 may be in a range of 1 to 10 nm.

A second insulating material 125 having a different etch selectivity from the first insulating material is deposited along an inner wall of the contact hole H. For example, the second insulating material 125 may include a silicon nitride layer.

Referring to FIG. 4B, the second insulating material 125 is anisotropically etched to form a spacer 130 on the inner wall of the contact hole H. The anisotropic etching process is performed so that a height h1 of the spacer 130 is 30 to 60 percentages of a height h2 of the contact hole H. An inner space of the contact hole H is divided into a first phase-change region A and a second phase-change region B by formation of the spacer 130. The first phase-change region A is a space in which a diameter thereof is reduced by the spacer 130 and the second phase-change region B is a space substantially having the same diameter as the contact hole H in which the spacer 130 is not present.

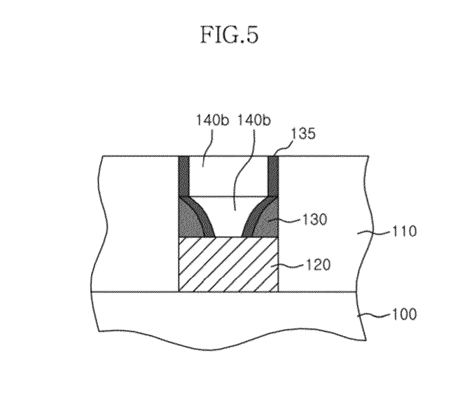

In some cases, after the process of forming the spacer 130 is completed, a nitride layer 135 is additionally covered in a sidewall of the contact hole as shown in FIG. 5. The nitride layer 135 may be conformally formed on the semiconductor substrate resultant 100 to be covered on the semiconductor substrate resultant 100 and then anisotropically etched to remain in a sidewall of the spacer 130 and the sidewall of the contact hole H. The nitride layer 135 may serve to additionally reduce the diameter of the contact hole H to reduce a melting energy for phase-change.

Referring to FIG. 4C, a phase-change material layer 140 is formed to be filled within the contact hole H. The phase-change materia layer 140 may include a chalcogenide compound containing germanium (Ge), antimony (Sb), and tellurium (Te). But, the inventive concept is not limited thereto and any material in which its resistance is varied by a heat included thereto may be used. Then, a planarization process is performed on the phase-change material layer 140 until a surface of the interlayer insulating layer 110 is exposed, thereby burying the phase-change material layer 140 within the contact hole H as shown in FIG. 2.

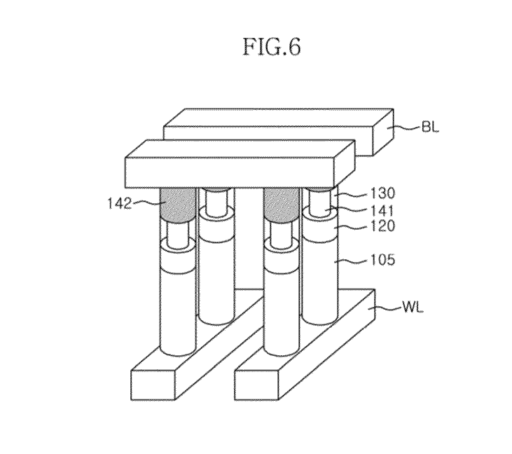

Alternatively, a first phase-change material layer 141 and a second phase-change material layer 142 may be formed of different material's from each other. In particular, the first phase-change material layer 141 is formed of a material having a lower phase-change temperature than the second phase-change material layer 142 and thus a difference between the first current I1 and the second current I2 can be increased. Therefore, it is possible to realize multi levels accurately. In FIG. 6, the reference numeral WL and BL may denote a word line and a bit line, respectively and the reference numeral 105 may denote a switching device.

In an embodiment, the first phase-change material layer 141 may be formed of a material having larger resistivity and a higher crystallization rate than the second phase-change material 142. From different points of view, the second phase-change material 142 may be formed of a material having smaller resistivity and a lower crystallization rate than the first phase-change material 142.

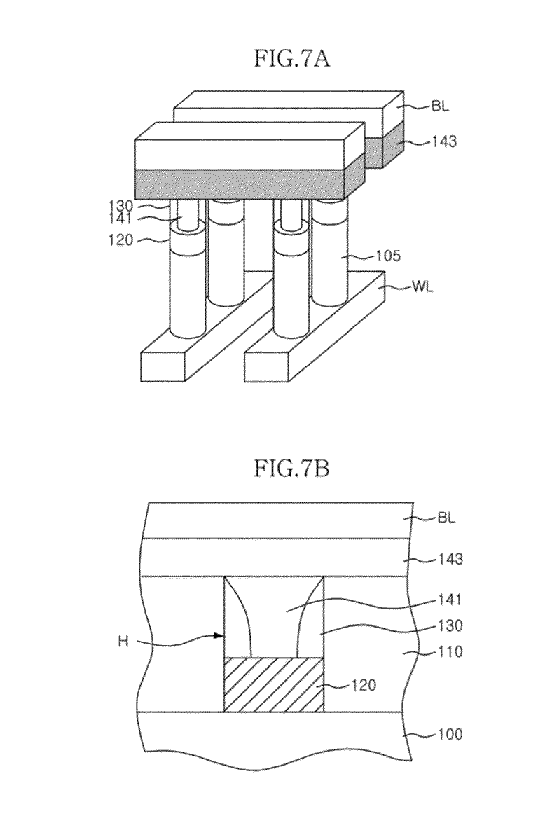

In addition, as shown in FIG. 7a, a first phase-change material layer 141 is formed in an inner space of a contact hole H (see in FIG. 7B) and a second phase-change material layer 143 is in contact with the first phase-change material layer 141 and extends to overlap a bit line BL.

At this time, as shown in FIG. 7B, a spacer 130 may be formed on an entire sidewall of the contact hole H and the first phase-change materia layer 141 is buried within the contact hole H. The second phase-change material layer 143 is deposited on the first phase-change materia layer 141 and a metal layer for a bit line is formed on the second phase-change material layer 143. The mewl layer for a bit line and the second phase-change material layer 143 are patterned in a direction orthogonal to a word line WL. At this time, the first phase-change material layer 141 and the second phase-change material layer 143 may include the same material or different materials. The reference numeral 110 denotes an interlayer insulating layer.

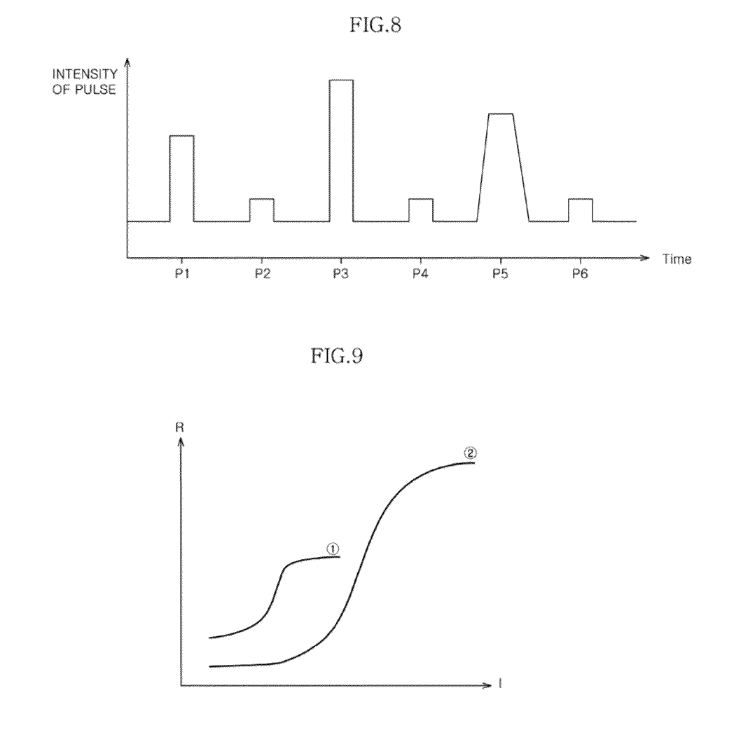

FIG. 8 is a graph explaining a driving of a phase-change memory device according to exemplary embodiments of the inventive concept.

First, when allowing the first phase-change material layer 140a or 141 of the first phase-change region A to be phase-changed, after a first write pulse P1 for phase-changing the first phase-change material layer 140a or 141 of the first phase-change region A is applied thereto, a read pulse P2 having a lower level than the first write pulse P1 is applied to read a resistance level of the phase-change material layer 140. At this time, the read pulse P2 is a current having a low level insignificant to phase-change the phase-change material layer 140.

When allowing the second phase-change material layer 140b, 142, or 143 of the phase-change region A and the phase-change region B to be phase-changed, after a second write pulse P3 having a higher level than the first write pulse P1 is applied, a read pulse P4 is applied again to read a resistance level of the phase-change material layer 140. The second phase-change material layer 140b, 142, or 143 corresponding to the second phase-change region B is phase-changed according to application of the second write pulse.

When an erase operation is performed, an erase pulse P5 is applied to bulkily erase data written in the first phase-change material layer 140a or 141 and the second phase-change material layer 140b, 142, or 143 and a read pulse P6 is applied to read a resistance level of the phase-change material layer 140.

As described above, according to the exemplary embodiment, it is possible to realize multi levels through structure modification of the phase-change region. That is, the phase-change memory device is configured of a phase-change material layer of multi layers having different sizes (widths) from each other. Since different sizes of the layers constituting the phase-change material layer cause different current densities for phase-change to be applied thereto, the multi layers of the phase-change material layer are phase-changed at different current levels and thus it is possible to realize multi levels stably and reproducibly.

The phase-change region according to the exemplary embodiment has a confined structure not to affect adjacent phase-change material layers. Therefore, even when a stepwise current is applied, there is no effect to the adjacent cells, thereby realizing multi levels stably.

Although the exemplary embodiment has illustrated that the phase-change material layer is divided into two phase-change regions, the inventive concept is not limited thereto and an example that the phase-change region is divided into multi layers using spacers is applied thereto.

While certain embodiments have been described above, it will be understood that the embodiments described are by way of example only. Accordingly, the devices and methods described herein should not be limited based on the described embodiments. Rather, the systems and methods described herein should only be limited in light of the claims that follow when taken in conjunction with the above description and accompanying drawings.

What is claimed is:

1. A phase-change memory device, comprising:
a first phase-change material layer to which a current is provided from a heating electrode; and
a second phase-change material layer formed with continuity to the first phase-change material layer and having a different width from the first phase-change material layer, and to which a current is provided from the heating electrode,
wherein the second phase-change material layer includes a material having smaller resistivity and a lower crystallization rate than the first phase-change material layer.

2. The device of claim 1, wherein the second phase-change material layer is disposed on the first phase-change material layer.

3. The device of claim 2, wherein a width of the first phase-change material layer is smaller than that of the second phase-change material layer.

4. The device of claim 1, wherein the first and second phase-change material layers are configured to be buried within spaces having different diameters, respectively.

5. The device of claim 1, wherein the first phase-change material layer is formed to be buried within a constant space and the second phase-change material layer is in contact with the first phase-change material layer and extends on the first phase-change material layer in a line shape.

6. A phase-change memory device, comprising:
a first phase-change region having a first caliber; and
a second phase-change region extended upwardly with continuity to the first phase-change region and having a second caliber greater than the first caliber,
wherein the second phase-change region includes a material having smaller resistivity and a lower crystallization rate than the first phase-change region.

7. The device of claim 6, wherein the first phase-change region further includes a spacer so that the first caliber is smaller than the second caliber by the spacer.

8. The device of claim 6, further comprising a heating electrode configured to provide a current to the first and second phase-change regions and formed below the first phase-change region.

9. The device of claim 8, wherein the first phase-change region is phase-changed by a first current having a first level providing from the heating electrode, and the second phase-change region is phase-changed by a second current having a second level higher than the first level providing from the heating electrode.

10. The device of claim 6, wherein the first and second phase-change regions are formed in one contact hole, and a spacer is further formed on a sidewall of in a lower portion of the contact hole to divide the first and second phase-change regions.

11. The device of claim 10, wherein a height of the spacer corresponds to 30 to 60 percentages of a height of the contact hole.

12. The device of claim 11 wherein a silicon nitride layer having a uniform thickness is further covered on a sidewall of the contact hole including the spacer.

13. The device of claim 6, wherein a first phase-change region is formed to be buried within a contact hole including a spacer formed on a sidewall thereof, and a second phase-change region is in contact with the first phase-change region and extends on the first phase-change region in a line shape.

14. A method of operating a phase-change memory device which includes a first phase-change material layer to which a current is provided from a heating electrode, and a second phase-change material layer formed with continuity to the first phase-change material layer and having a different width from the first phase-change material layer, and to which a current is provided from the heating electrode, wherein the second phase-change material layer includes a material having smaller resistivity and a lower crystallization rate than the first phase-change material layer, the method comprising:
to selectively program only the first phase-change material layer, providing a first current having a first level for allowing only the first phase-change material layer to be phase-changed.

15. The method of claim 14, wherein a second current having a second level higher than the first level is supplied to program the first phase-change material leer and the second phase-change material layer.

16. The method of claim 15, wherein an erase pulse is supplied to bulkily erase the first phase-change material layer and the second phase-change material layer.

17. The method of claim 14, wherein the first current is supplied for a preset first time to program the first phase-change material layer, and the first current is supplied for a second time larger than the first time to program the first phase-change material layer and the second phase-change material layer.

18. The method of claim 17, wherein an erase pulse is supplied to bulkily erase the first phase-change material layer and the second phase-change material layer.

19. A method of operating a phase-change memory device which includes a first phase-change material layer to which a current is provided from a heating electrode, and a second phase-change material layer formed with continuity to the first phase-change material layer and having a different width from the first phase-change material layer, and to which a current is provided from the heating electrode, wherein the second phase-change material layer includes a material having smaller resistivity and a lower crystallization rate than the first phase-change material layer, the method comprising:
supplying a write pulse to at least one of the first phase-change material layer and the second phase-change material layer through the heating electrode to program the phase-change memory device.

20. The method of claim 19, wherein an erase pulse is supplied to bulkily erase the first phase-change material layer and the second phase-change material layer.
